(19) United States
(12) Patent Application Publication
(10) Pub. No.: US 2024/0371720 A1
(43) Pub. Date: Nov. 7, 2024

(54) SEMICONDUCTOR PACKAGE AND METHOD FOR FORMING THE SAME

(71) Applicant: STATS ChipPAC Pte. Ltd., Singapore (SG)

(72) Inventors: OhYoung KWON, Seoul (KR); YongTaek LEE, Seoul (KR); SeungMan HONG, Incheon (KR)

(21) Appl. No.: 18/650,077

(22) Filed: Apr. 30, 2024

(30) Foreign Application Priority Data
May 5, 2023 (CN) 202310495319.5

(51) Int. Cl. H01L 23/367; H01L 21/56; H01L 23/00; H01L 23/31; H01L 23/42; H01L 25/00; H01L 25/065

(52) U.S. Cl. CPC H01L 23/367; H01L 21/56; H01L 23/3121; H01L 23/42; H01L 24/32; H01L 24/48; H01L 24/73; H01L 24/83; H01L 24/85; H01L 25/0655; H01L 25/50; H01L 2224/32245; H01L 2224/48225; H01L 2224/73215; H01L 2224/83; H01L 2224/85

(57) ABSTRACT

A semiconductor package is provided. The semiconductor package includes: a substrate having a substrate surface, wherein the substrate includes conductive patterns on the substrate surface; a first semiconductor die attached onto the substrate surface; a heat spreader mounted over and thermally coupled to the first semiconductor die, wherein the heat spreader includes an overhanging portion that extends laterally beyond the first semiconductor die; at least one second semiconductor die attached onto the spreader bottom surface of the overhanging portion and beneath the overhanging portion of the heat spreader, wherein the at least one second semiconductor die is thermally coupled to the overhanging portion of the heat spreader, and is electrically coupled to at least one of the conductive patterns of the substrate; and an encapsulant layer for encapsulating the first semiconductor die, the at least one second semiconductor die, the heat spreader and the conductive patterns on the substrate surface.

### TECHNICAL FIELD

The present application generally relates to semiconductor devices, and more particularly, to a semiconductor package with improved space efficiency and a method for making a semiconductor package.

### BACKGROUND OF THE INVENTION

The semiconductor industry is constantly faced with complex integration challenges as consumers want their electronics to be smaller, faster and higher performance with more and more functionalities packed into a single device. The space of a package needs to be utilized efficiently. However, if the layout of the package is too tight, the thermal efficiency may be harmed, and the total performance of the semiconductor device may be affected.

Therefore, a need exists for an improved package design for integrating multiple components.

### SUMMARY OF THE INVENTION

An objective of the present application is to provide a semiconductor package with improved space-efficiency.

According to an aspect of embodiments of the present application, a semiconductor package is provided. The semiconductor package includes: a substrate having a substrate surface, wherein the substrate includes conductive patterns on the substrate surface; a first semiconductor die attached onto the substrate surface; a heat spreader mounted over and thermally coupled to the first semiconductor die, wherein the heat spreader includes an overhanging portion that extends laterally beyond the first semiconductor die, wherein the overhanging portion has a spreader bottom surface facing towards the substrate surface; at least one second semiconductor die attached onto the spreader bottom surface of the overhanging portion and beneath the overhanging portion of the heat spreader, wherein the at least one second semiconductor die is thermally coupled to the overhanging portion of the heat spreader, and is electrically coupled to at least one of the conductive patterns of the substrate; and an encapsulant layer encapsulating the first semiconductor die, the at least one second semiconductor die, the heat spreader and the conductive patterns on the substrate surface.

According to an aspect of embodiments of the present application, a method for making a semiconductor package is provided, the method includes: providing a substrate having a substrate surface, wherein the substrate includes conductive patterns formed on the substrate surface and a first semiconductor die attached onto the substrate surface; providing a heat spreader having a spreader bottom surface and at least one second semiconductor die, wherein the at least one second semiconductor die is attached onto the spreader bottom surface; attaching the heat spreader onto the first semiconductor die such that a portion of the heat spreader with the at least one second semiconductor die overhangs from the first semiconductor die; forming at least one electrical connection to electrically connect the at least one second semiconductor die with at least one of the conductive patterns of the substrate; and forming an encapsulant layer on the substrate to encapsulate the first semiconductor die, the at least one second semiconductor die, the heat spreader, the at least one electrical connection and the conductive patterns of the substrate.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1 and 2 are cross-sectional views illustrating a semiconductor package according to two embodiments of the present application.

FIGS. 3A to 3F are cross-sectional views illustrating a method for making a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

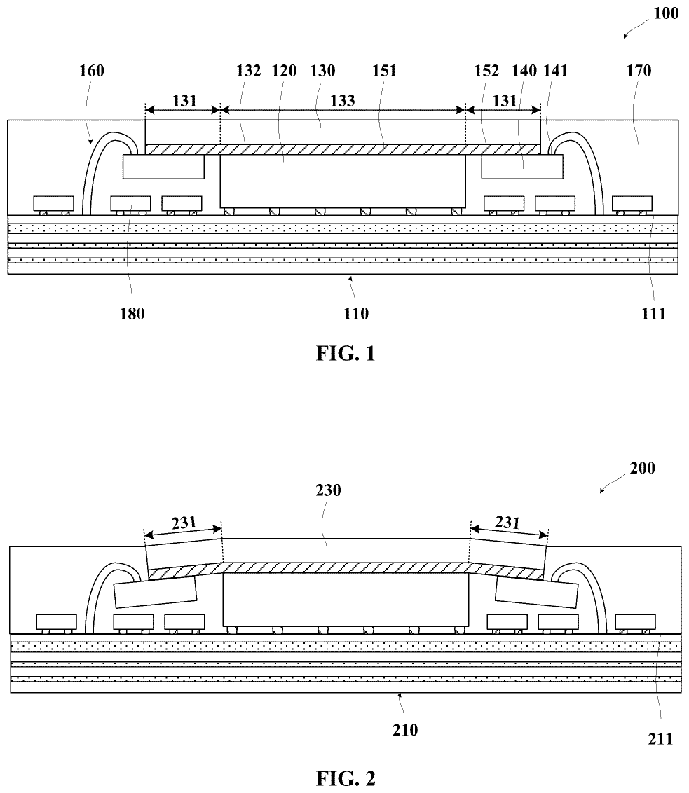

FIG. 1 illustrates a cross-sectional view illustrating a semiconductor package 100 according to an embodiment of the present application. The semiconductor package 100 includes a substrate 110 having a substrate surface 111. The substrate 110 includes conductive patterns (not shown) on the substrate surface 111. In some embodiments, the conductive patterns on the substrate surface 111 include traces for routing signals and contacts for mounting devices. The conductive patterns may include patterned thin copper (Cu) foil. In some embodiments, the substrate 110 may be a printed circuit board (PCB) and may include a redistribution structure (RDS) having one or more dielectric layers and one or more conductive layers between and through the dielectric layers. The conductive layers may define pads, traces, and plugs through which electrical signals or voltages can be distributed horizontally and vertically across the RDS. In some embodiments, the RDS may include a plurality of conductive patterns formed on both or either of the top and bottom surfaces of the substrate 110. It can be understood that the substrate 110 may be other components for forming desired electronic connection of electronic components thereon.

Still referring to FIG. 1, a first semiconductor die 120 is attached onto the substrate surface 111 via an electronic connection such as solder balls. A heat spreader 130 is mounted over and thermally coupled to the first semiconductor die 120. The heat spreader 130 includes an overhanging portion 131 that extends laterally beyond the first semiconductor die 120, wherein the overhanging portion 131 has a spreader bottom surface 132 facing towards the substrate surface 111. As shown in FIG. 1, in some embodiments, the overhanging portion 131 extends horizontally with respect to the substrate surface 111. As shown in further embodiments, the overhanging portion 131 may have other orientations.

Still referring to FIG. 1, at least one second semiconductor die 140 is attached onto the spreader bottom surface 132 of the overhanging portion 131 and beneath the overhanging portion 131 of the heat spreader 130. The at least one second semiconductor die 140 is thermally coupled to the overhanging portion 131 of the heat spreader 130. In some embodiments, the overhanging portion 131 is at a periphery of the heat spreader 130. In some embodiments, the at least one second semiconductor die 140 may be attached to the overhanging portion 131 via a first adhesion layer 152. The first adhesion layer 152 may include one or both of a thermal interface material or a die adhesive film. In some embodiments, the thermal interface material may include thermal epoxy, thermal epoxy resin, thermal conductive paste, aluminum oxide, zinc oxide, boron nitride, pulverized silver, or thermal grease. In some embodiments, the die adhesive film may include a non-conductive film, an anisotropic conductive film, an ultraviolet (UV) film, an instant adhesive, a thermosetting adhesive, or any other suitable adhesive materials. Although the first adhesion layer 152 is used to attach the at least one second semiconductor die 140 to the overhanging portion 131 of the heat spreader 130 in the example shown in FIG. 1, the present application is not limited thereto. In some other embodiments, the at least one second semiconductor die 140 may be attached to the overhanging portion 131 of the heat spreader 130 via mechanical attachments such as fasteners (not shown). For example, fasteners may be threaded fasteners (e.g., screws), rivets, pins, clips, etc.

In some embodiments, a top surface of the at least one second semiconductor die 140 includes a portion 141 exposed from the spreader bottom surface 132 of the overhanging portion 131, and the exposed portion 141 includes at least one conductive structure (not shown) for electrically coupling the at least one second semiconductor die 140 to at least one of the conductive patterns of the substrate 110. It can be understood that, in some other embodiments, the bottom surface of the at least one second semiconductor die 140 may also include conductive structures for electrical connection.

Still referring to FIG. 1, in some embodiments, the heat spreader 130 is mounted over and thermally coupled to the first semiconductor die 120 via a second adhesion layer 151. The second adhesion layer 151 may include one or both of a thermal interface material or a die adhesive film. In some embodiments, a central portion 133 of the heat spreader 130 is mounted over the first semiconductor die 120. In the embodiment shown in FIG. 1, the first adhesion layer 152 for attaching the at least one second semiconductor die 140 and the second adhesion layer 151 for attaching the first semiconductor die 120 are different portions of a continuous adhesion layer covering the entire bottom surface of the heat spreader 130. In some other embodiments, the first adhesion layer 152 and the second adhesion layer 151 are not connected with each other. In some embodiments, the first adhesion layer 152 may be initially formed on the heat spreader 130 or on the at least one second semiconductor die 140. In some embodiments, the second adhesion layer 151 may be initially formed on the heat spreader 130 or on the first semiconductor die 120. The first adhesion layer 152 and the second adhesion layer 151 may or may not be formed in a same process, and may or may not include the same material. The configuration of the material at the adhesion layers 151 and 152 may vary according to actual needs.

Still referring to FIG. 1, the at least one second semiconductor die 140 is electrically coupled to at least one of the conductive patterns of the substrate 110. Preferably, the at least one second semiconductor die 140 is electrically coupled to the at least one of the conductive patterns on the substrate surface 111 via at least one bonding wire 160.

Still referring to FIG. 1, in some embodiments, the semiconductor package 100 also includes at least one electronic component 180 attached onto the substrate surface 111 and besides the first semiconductor die 120. In some embodiments, the at least one electronic component 180 is under the at least one second semiconductor die 140. In some embodiments, the at least one electronic component 180 may include active electronic components such as bipolar or field effect transistors, or passive electronic components such as resistors, capacitors, or inductors. The passive and active electronic components can be electrically connected to form circuits, which enable the semiconductor package to perform high-speed calculations and other useful functions.

Still referring to FIG. 1, the semiconductor package 100 also includes an encapsulant layer 170 encapsulating the first semiconductor die 120, the at least one second semiconductor die 140, the at least one electronic component 180, the heat spreader 130 and the conductive patterns on the substrate surface 111.

It can be seen that, in the semiconductor package 100 according to the present application, the space can be used more efficiently by arranging multiple semiconductor dice in parallel rather than in series. Accordingly, the semiconductor package according to the present application is space-efficient, and has higher integration density. Also, by arranging multiple dies in parallel rather than serially, the form factor of the semiconductor package is reduced and the risk of package warpage can be mitigated. Further, both the first semiconductor die 120 and the at least one second semiconductor die 140 are directly attached to the heat spreader 130, the heat dissipation is rather efficient for the semiconductor dice herein.

FIG. 2 illustrates a cross-sectional view illustrating a semiconductor package 200 according to another embodiment of the present application. As shown in FIG. 2, the semiconductor package 200 may have similar structures and configurations as the semiconductor package 100 shown in FIG. 1, except that the overhanging portion 231 of the heat spreader 230 is inclined towards the substrate surface 211 of the substrate 210.

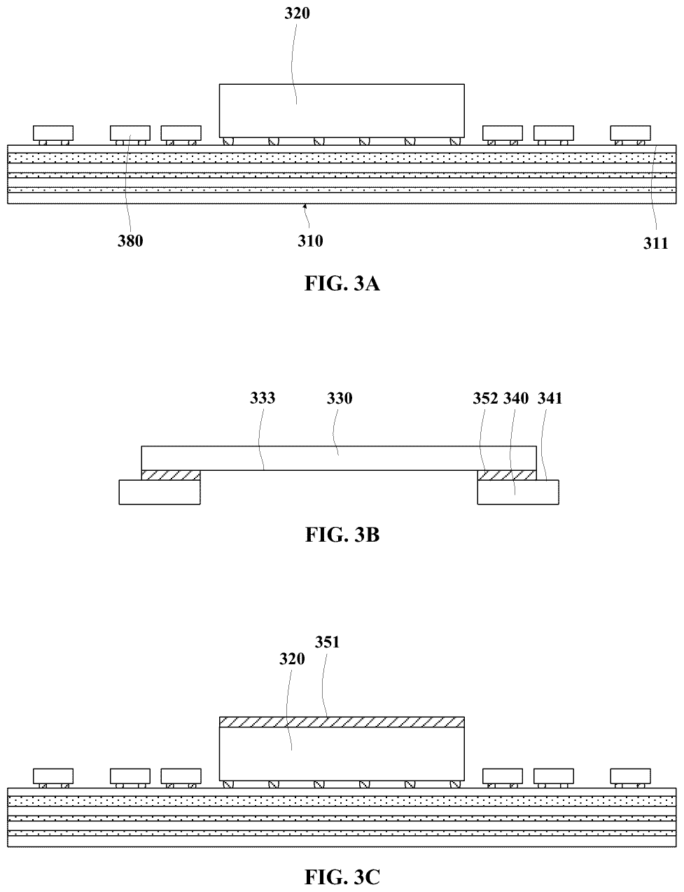

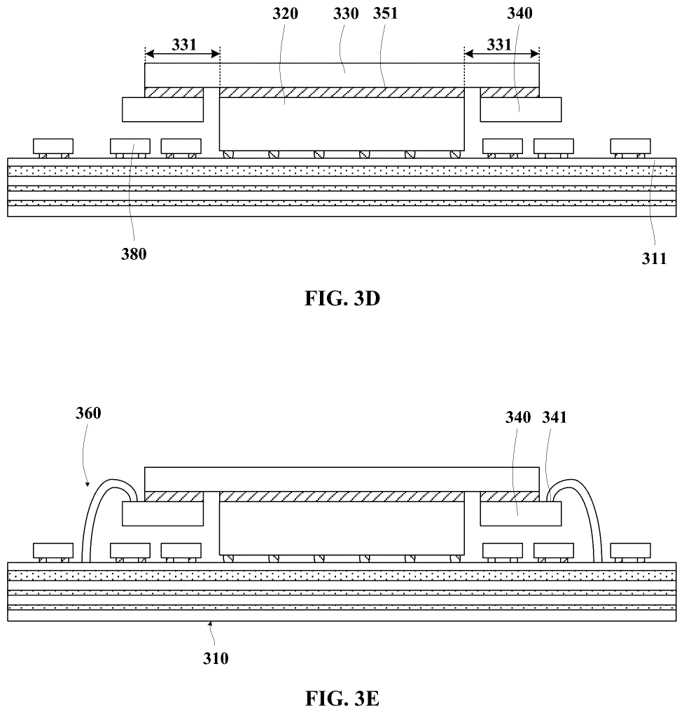

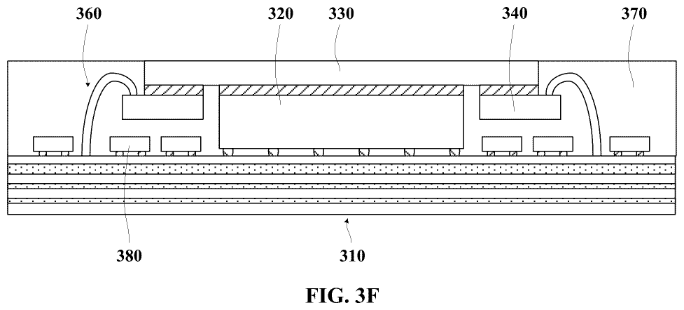

FIGS. 3A to 3F are cross-sectional views illustrating a method for making a semiconductor package according to an embodiment of the present application.

According to the present application, a method for forming an aforementioned semiconductor package is provided.

Referring to FIG. 3A, a substrate 310 having a substrate surface 311 is provided. The substrate 310 includes conductive patterns (not shown) on the substrate surface 311 and a first semiconductor die 320 is attached onto the substrate surface 311. In some embodiments, at least one electronic component 380 is attached onto the substrate surface 311 besides the first semiconductor die 320. The first semiconductor die 320 and the at least one electronic component 380 may be attached onto the substrate surface 311 in a same process or in different processes.

Referring to FIG. 3B, a heat spreader 330 having a spreader bottom surface 333 and at least one second semiconductor die 340 are provided. The at least one second semiconductor die 340 is attached onto the spreader bottom surface 333. In some embodiments, the at least one second semiconductor die 340 may be attached at a periphery of the spreader bottom surface 333 of the heat spreader 130. In some embodiments, a top surface of the at least one second semiconductor die 340 includes a portion 341 exposed from the spreader bottom surface 333, and the exposed portion 341 includes at least one conductive structure (not shown) for electrically coupling the at least one second semiconductor die 340 to the at least one of the conductive patterns of the substrate 310 in further steps.

Still referring to FIG. 3B, in some embodiments, the step of providing a heat spreader 330 having a spreader bottom surface 333 and at least one second semiconductor die 340 also includes: attaching the at least one second semiconductor die 340 onto the spreader bottom surface 333 via a first adhesion layer 352. The first adhesion layer 352 may include one or both of a thermal interface material or a die adhesive film. The thermal interface material may be formed by applying thermal epoxy, thermal epoxy resin, thermal conductive paste, aluminum oxide, zinc oxide, boron nitride, pulverized silver, or thermal grease onto a desired area for attachment. The die adhesive film can be a sheet containing one or more layers of an epoxy film, and can be formed with a roller or press. As shown in FIG. 3B, in the case where multiple second semiconductor dice 340 are attached, they may be attached at the same or different time with the same or different thermal interface material or die adhesive film material. In some embodiments, the heat spreader 330 can be attached to the at least one second semiconductor die 340 prior to the attachment of the heat spreader 330 onto the first semiconductor die 320 as further illustrated, such that the at least one second semiconductor die 340 may be easily attached to the spreader bottom surface 333.

Referring to FIG. 3C, in some embodiments, the method of the present application also includes: forming a second adhesion layer 351 on the first semiconductor die 320. The second adhesion layer 351 may also include one or both of a thermal interface material or a die adhesive film.

It can be understood that, in some other embodiments, instead of forming the second adhesion layer 351 on the first semiconductor die 320, the second adhesion layer 351 may also be formed on the spreader bottom surface 333 of the heat spreader 330. The first adhesion layer 352 and the second adhesion layer 351 may be continuous or discontinuous.

Referring to FIG. 3D, the heat spreader 330 is attached onto the first semiconductor die 320 such that a portion 331 of the heat spreader 330 attached with the at least one second semiconductor die 340 overhangs from the first semiconductor die 320. In some embodiments, the heat spreader 330 is attached to and thermally coupled to the first semiconductor die 320 via the second adhesion layer 351. In some embodiments, the heat spreader 330 is attached to the first semiconductor die 320 at the central portion of the heat spreader 330. In some embodiments, the at least one electronic component 380 is under the at least one second semiconductor die 340 after the attachment of the heat spreader 330.

In the embodiment illustrated in FIG. 3D, the portion 331 of the heat spreader overhanging from the first semiconductor die 320 extends horizontally with respect to the substrate surface 311. It can be understood that, in some other embodiments, the portion 331 of the heat spreader overhanging from the first semiconductor die may be inclined towards the substrate surface 311.

Referring to FIG. 3E, at least one electrical connection 360 is formed to electrically connect the at least one second semiconductor die 340 with at least one of the conductive patterns of the substrate 310. Preferably, the at least one electrical connection 360 is formed by a wire bonding process. In some embodiments, the conductive structure of the exposed portion 341 of the top surface of the at least one second semiconductor die 340 is electrically coupled to the at least one of the conductive patterns of the substrate 310 via the at least one electrical connection 360.

Referring to FIG. 3F, an encapsulant layer 370 is formed on the substrate 310 to encapsulate the first semiconductor die 320, the at least one second semiconductor die 340, the heat spreader 330, the at least one electrical connection 360 and the conductive patterns of the substrate 310. In some embodiments, the encapsulant layer 370 also encapsulates the at least one electronic component 380. In some embodiments, a top surface of the heat spreader 330 may be exposed from the encapsulant layer 370. In some embodiments, the encapsulant layer 370 may be formed by depositing an encapsulant or molding compound on the substrate 310 using injection molding, compressive molding, transfer molding, liquid encapsulant molding, vacuum lamination, spin coating, or another suitable processes. The encapsulant layer 370 may include a polymer composite material, such as epoxy resin, epoxy acrylate, or any suitable polymer with or without filler. The encapsulant layer 370 may be non-conductive, provide structural support, and environmentally protect the electronic devices from external elements and contaminants. In some embodiments, the method may further include forming a ball grid array on the bottom surface of the substrate 310 for providing electrical connection of the semiconductor package with other devices.

The discussion herein included numerous illustrative figures that showed various portions of a semiconductor package and method for making a semiconductor package. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a substrate having a substrate surface, wherein the substrate comprises conductive patterns on the substrate surface;
a first semiconductor die attached onto the substrate surface;
a heat spreader mounted over and thermally coupled to the first semiconductor die, wherein the heat spreader comprises an overhanging portion that extends laterally beyond the first semiconductor die, wherein the overhanging portion has a spreader bottom surface facing towards the substrate surface;
at least one second semiconductor die attached onto the spreader bottom surface of the overhanging portion and beneath the overhanging portion of the heat spreader, wherein the at least one second semiconductor die is thermally coupled to the overhanging portion of the heat spreader, and is electrically coupled to at least one of the conductive patterns of the substrate; and
an encapsulant layer encapsulating the first semiconductor die, the at least one second semiconductor die, the heat spreader and the conductive patterns on the substrate surface.

2. The semiconductor package of claim 1, wherein the at least one second semiconductor die is attached onto the spreader bottom surface of the overhanging portion via a thermal interface material or a die adhesive film.

3. The semiconductor package of claim 1, wherein the heat spreader is mounted over and thermally coupled to the first semiconductor die via a thermal interface material or a die adhesive film.

4. The semiconductor package of claim 1, further comprising: at least one electronic component attached onto the substrate surface and besides the first semiconductor die, wherein the at least one electronic component is under the at least one second semiconductor die.

5. The semiconductor package of claim 1, wherein the overhanging portion of the heat spreader extends horizontally with respect to the substrate surface.

6. The semiconductor package of claim 1, wherein the overhanging portion of the heat spreader is inclined towards the substrate surface.

7. The semiconductor package of claim 1, wherein the at least one second semiconductor die is electrically coupled to the at least one of the conductive patterns on the substrate surface via wire bonding.

8. The semiconductor package of claim 1, wherein a top surface of the at least one second semiconductor die comprises an exposed portion from the spreader bottom surface of the overhanging portion, wherein the exposed portion comprises at least one conductive structure for electrically coupling to the at least one of the conductive patterns of the substrate.

9. A method for forming a semiconductor package, comprising:
providing a substrate having a substrate surface, wherein the substrate comprises conductive patterns formed on the substrate surface and a first semiconductor die attached onto the substrate surface;
providing a heat spreader having a spreader bottom surface and at least one second semiconductor die, wherein the at least one second semiconductor die is attached onto the spreader bottom surface;
attaching the heat spreader onto the first semiconductor die such that a portion of the heat spreader attached with the at least one second semiconductor die overhangs from the first semiconductor die;
forming at least one electrical connection to electrically connect the at least one second semiconductor die with at least one of the conductive patterns of the substrate; and
forming an encapsulant layer on the substrate to encapsulate the first semiconductor die, the at least one second semiconductor die, the heat spreader, the at least one electrical connection and the conductive patterns of the substrate.

10. The method of claim 9, wherein providing a heat spreader having a spreader bottom surface and at least one second semiconductor die comprises:
attaching the at least one second semiconductor die onto the spreader bottom surface via a thermal interface material or a die adhesive film.

11. The method of claim 9, wherein attaching the heat spreader onto the first semiconductor die comprises:
forming a thermal interface material or a die adhesive film on the first semiconductor die; and
attaching the heat spreader onto the first semiconductor die via the thermal interface material or the die adhesive film.

12. The method of claim 9, further comprising:
attaching at least one electronic component onto the substrate surface of the substrate and besides the first semiconductor die, wherein upon attaching the heat spreader onto the first semiconductor die, the at least one electronic component is under the at least one second semiconductor die.

13. The method of claim 9, wherein upon attaching the heat spreader onto the first semiconductor die, the portion of the heat spreader overhanging from the first semiconductor die extends horizontally with respect to the substrate surface.

14. The method of claim 9, wherein upon attaching the heat spreader onto the first semiconductor die, the portion of the heat spreader overhanging from the first semiconductor die is inclined towards the substrate surface.

15. The method of claim 9, wherein forming at least one electrical connection to electrically connect the at least one second semiconductor die with at least one of the conductive patterns of the substrate comprises:
forming at least one bonding wire to electrically connect the at least one second semiconductor die with the at least one of the conductive patterns of the substrate.

16. The method of claim 9, wherein providing a heat spreader having a spreader bottom surface and at least one second semiconductor die comprises:
attaching a first portion of a top surface of the at least one second semiconductor die onto the spreader bottom surface, wherein a second portion of the top surface of the at least one second semiconductor exposed from the spreader bottom surface has at least one conductive structure formed thereon.

17. The method of claim 16, wherein forming at least one electrical connection to electrically connect the at least one second semiconductor die with at least one of the conductive patterns of the substrate comprises:
forming at least one electrical connection to electrically connect the conductive structure formed on the second portion of the top surface of the at least one second semiconductor with the at least one of the conductive patterns of the substrate.
